(19) United States
(12) Patent Application Publication
(10) Pub. No.: US 2024/0194677 A1
(43) Pub. Date: Jun. 13, 2024

(54) PREVENTING SOURCE/DRAIN EPI MERGE WITHOUT CELL SIZE INCREASE

(71) Applicant: INTERNATIONAL BUSINESS MACHINES CORPORATION, ARMONK, NY (US)

(72) Inventors: Min Gyu Sung, Latham, NY (US); Julien Frougier, Albany, NY (US); Ruilong Xie, Niskayuna, NY (US); Chanro Park, Clifton Park, NY (US); Juntao Li, Cohoes, NY (US)

(21) Appl. No.: 18/064,260

(22) Filed: Dec. 10, 2022

(51) Int. Cl. H01L 27/092; H01L 21/02; H01L 21/8238; H01L 29/06; H01L 29/423; H01L 29/66; H01L 29/775

(52) U.S. Cl. CPC H01L 27/092; H01L 21/02532; H01L 21/02603; H01L 21/823807; H01L 21/823814; H01L 29/0673; H01L 29/42392; H01L 29/66439; H01L 29/775

(57) ABSTRACT

A semiconductor device includes a first nanosheet field effect transistor (PET) having a first gate stack arranged on a substrate. A second nanosheet FET is arranged on the substrate adjacent to the first nanosheet FET. The second FET includes a second gate stack, wherein a top of the first gate stack and a top of the second gate stack have different heights.

### BACKGROUND

### Technical Field

The present disclosure generally relates semiconductor devices, and more particularly, to SRAM constructed with nanosheet Field Effect Transistors (FET).

### Description of the Related Art

In SRAM cells, there are gate stacks of nanosheets with neighboring devices having a source/drain (S/D) epitaxial (referred to as “epi”) grown on the cell that is typically diamond-shaped. Particularly in a case where FET pull-up and pull-down device are arranged, the epi S/D diamonds may contact each other causing a short of the neighboring devices.

### SUMMARY

According to one embodiment, a semiconductor device includes a first nanosheet field effect transistor (FET) arranged on a substrate, wherein the first FET includes a first gate stack. A second nanosheet FET is arranged on the substrate adjacent to the first nanosheet FET. The second FET includes a second gate stack. A top of the first gate stack and a top of the second gate stack have different heights.

In one embodiment, a first channel of the first gate stack extends from the bottom of the first gate stack and has a first height. A second channel of the second gate stack extends from the bottom of the second gate stack and has a second height. The first height of the first channel is different than the second height of the second channel based on a difference in channel heights of the substrate.

In one embodiment, the first height of the first channel is different than the second height of the second channel additionally based on a metal gate height having a distance between two adjacent channels in the first gate stack and the second gate.

In one embodiment, the first FET is a pull-up (PU) PFET, and the second FET is a pull-down (PD) NFET.

In one embodiment, an S/D epitaxial growth on the PU PFET and on the PD NFET are offset by a difference in channel height of the first height of the first channel and the second height of the second channel.

In one embodiment, the substrate includes a stepped upper surface. The PU PFET is arranged on higher portion of the stepped upper surface. The PD NFET is arranged on a lower portion of the stepped upper surface.

In one embodiment, a shallow trench isolation (STI) SiO₂ recess is connected to the PU PFET and the PD NFET to fill different depths on an upper surface of the substrate.

In one embodiment, the substrate includes Si having a pattern with different recess depths, wherein the substrate is arranged below a Bottom Dielectric Isolation (BDI) layer.

In one embodiment, there are a same number of nanosheets for each nanosheet FET on the Si pattern.

In one embodiment, a same number of nanosheets have a same total nanosheet height. The total nanosheet height includes a channel height, a dummy SiGe layer, and the BDI layer.

According to one embodiment, a method of preventing a source/drain (S/D) epi merge includes providing a first nanosheet fin including a first field effect transistor (FET) on a substrate. The first FET includes a first gate stack. A second nanosheet fin including a second FET is provided on the substrate adjacent to the first nanosheet FET. The second FET includes a second gate stack. A top of the first gate stack is a different height than a top of the second gate stack.

In one embodiment, the method includes forming a step on the surface of the substrate so that the first gate stack is offset in height from the second gate stack.

In one embodiment, the method includes forming the first nanosheet fin and the second nanosheet fin on the substrate to have equal lengths.

In one embodiment, the method includes providing the first nanosheet fin on a higher portion of the stepped substrate surface and the second nanosheet fin on a lower portion of the stepped substrate surface.

In one embodiment, the first FET provided on the first nanosheet fin comprises a pull-up (PU) PFET, and the second FET provided on the second nano fin comprises a pull-down (PD) NFET.

In one embodiment, the method includes providing a first channel that extends from the bottom of the first gate stack and has a first height, and providing a second channel that extends from the bottom of the second gate stack and has a second height. The first height of the first channel is different than the second height of the second channel by at least a difference in channel heights of the substrate.

In one embodiment, the method includes providing a first metal gate on the first nanosheet FET and a second metal gate on the second nanosheet FET. The first height of the first channel is different than the second height of the second channel by the difference in channel heights and by a metal gate height distance between the first channel and the second channel in the first gate stack and the second gate.

According to one embodiment, a method of forming a semiconductor device includes forming a stepped portion on a substrate surface. A first gate nanosheet stack with alternating layers of different semiconductor materials is formed on the stepped portion of the substrate surface. A second nanosheet gate stack with alternating layers of different semiconductor materials is formed on a non-stepped portion of the substrate surface. The first nanosheet gate stack and the second nanosheet gate stack are patterned to create respective nanosheet fins. An upper surface of the first nanosheet fin is higher than an upper surface of the second nanosheet fin. An epitaxial source/drain (S/D) is grown on each of the first nanosheet fin and the second nanosheet fin.

In one embodiment, the epitaxial S/D is grown on a side of each nanosheet fin and has different respective height on the stepped portion than the non-stepped portion of the substrate.

In one embodiment, the alternating layers of different semiconductor materials include Si and SiGe, and the method further includes providing an STI of SiO₂ on surface of the substrate.

### BRIEF DESCRIPTION OF THE DRAWINGS

The drawings are of illustrative embodiments. They do not illustrate all embodiments. Other embodiments may be used in addition to or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1A and FIG. 1B provide a respective front overview of a conventional SRAM cell and an SRAM device with an offset gate stack, consistent with an illustrative embodiment.

FIG. 2A shows the forming of an optical planarizing layer (OPL) coating on a substrate for block patterning, consistent with an illustrative embodiment.

FIG. 2B shows a top view identifying the cross-section shown in FIG. 2A, consistent with an illustrative embodiment.

FIG. 3A shows the forming of an recess on the substrate, consistent with an illustrative embodiment.

FIG. 3B shows a top view identifying the cross-section shown in FIG. 3A, consistent with an illustrative embodiment.

FIG. 4A illustrates the optical planarizing layer removal from the substrate, consistent with an illustrative embodiment.

FIG. 4B shows a top view identifying the cross-section shown in FIG. 4A, consistent with an illustrative embodiment.

FIG. 5A illustrates the alternating layers of Si/SiGe stack growth, consistent with an illustrative embodiment.

FIG. 5B is a top view identifying the cross-sectional views of FIG. 5A consistent with an illustrative embodiment.

FIG. 6A shows nanosheet patterning of the nanosheet fins, consistent with an illustrative embodiment.

FIG. 6B is a top view identifying cross-sectional views including cut A of FIG. 6A, consistent with an illustrative embodiment.

FIG. 7A illustrates a shallow trench isolation (STI) and SiO₂ gap fill of the substrate surface and recess, consistent with an illustrative embodiment.

FIG. 7B is a top view identifying the cross-sectional views including cut A of FIG. 7A, consistent with an illustrative embodiment.

FIGS. 8A, 8B, and 8C are cross-sectional views of a gate patterning operation, consistent with an illustrative embodiment.

FIG. 8D is a top view identifying the cross-sectional views (Cut A, Cut B, and Cut C) of FIGS. 8A, 8B, and 8C, consistent with an illustrative embodiment.

FIGS. 9A, 9B, and 9C are cross-sectional views showing removal of the SiGe 50% layer, consistent with an illustrative embodiment.

FIG. 9D is a top view identifying the cross-sectional views (Cut A, Cut B, and Cut C) of FIGS. 9A, 9B, and 9C, consistent with an illustrative embodiment.

FIGS. 10A, 10B, and 10C are cross-sectional views showing the gate spacer deposit, consistent with an illustrative embodiment.

FIG. 10D is a top view identifying the cross-sectional views (Cut A, Cut B, and Cut C) of FIGS. 10A, 10B, and 10C, consistent with an illustrative embodiment.

FIGS. 11A, 11B, and 11C are cross-sectional views showing the gate spacer being etched back, consistent with an illustrative embodiment.

FIG. 11D is a top view identifying the cross-sectional views (Cut A, Cut B, and Cut C) of FIGS. 11A, 11B, and 11C, consistent with an illustrative embodiment.

FIGS. 12A, 12B, and 12C are cross-sectional views a nanosheet pull-down of the spacer pull-down at a sidewall of the nanosheets, consistent with an illustrative embodiment.

FIG. 12D is a top view identifying the cross-sectional views (Cut A, Cut B, and Cut C) of FIGS. 12A, 12B, and 12C, consistent with an illustrative embodiment.

FIGS. 13A, 13B, and 13C are cross-sectional views of an inner space formation of a nanosheet recess, consistent with an illustrative embodiment.

FIG. 13D is a top view identifying the cross-sectional views (Cut A, Cut B, and Cut C) of FIGS. 13A, 13B, and 13C, consistent with an illustrative embodiment.

FIGS. 14A, 14B, and 14C are cross-sectional views of an S/D epi growth at the sidewalls of the nanosheets, consistent with an illustrative embodiment.

FIG. 14D is a top view identifying the cross-sectional views (Cut A, Cut B, and Cut C) of FIGS. 14A, 14B, and 14C, consistent with an illustrative embodiment.

FIG. 15 is a perspective view of a semiconductor device consistent with an illustrative embodiment.

FIG. 16 is a flowchart illustrating a method of forming a semiconductor consistent with an illustrative embodiment.

### DETAILED DESCRIPTION

### Overview

In the following detailed description, numerous specific details are set forth by way of examples to provide a thorough understanding of the relevant teachings. However, it should be understood that the present teachings may be practiced without such details. In other instances, well-known methods, procedures, components, and/or circuitry have been described at a relatively high level, without detail, to avoid unnecessarily obscuring aspects of the present teachings. It is to be understood that the present disclosure is not limited to the depictions in the drawings, as there may be fewer elements or more elements than shown and described.

In discussing the present technology, it may be helpful to describe various salient terms. In one aspect, spatially related terminology such as “front,” “back,” “top,” “bottom,” “beneath,” “below,” “lower,” above,” “upper,” “side,” “left,” “right,” and the like, is used with reference to the direction of the Figures being described. Since components of embodiments of the disclosure can be positioned in a number of different directions, the directional terminology is used for purposes of illustration and is in no way limiting. Thus, it will be understood that the spatially relative terminology is intended to encompass different directions of the device in use or operation in addition to the direction depicted in the figures. For example, if the device in the figures is turned over, elements described as “below” or “beneath” other elements or features would then be oriented “above” the other elements or features. Thus, for example, the term “below” can encompass both an orientation that is above, as well as, below. The device may be otherwise oriented (rotated 90 degrees or viewed or referenced at other directions) and the spatially relative descriptors used herein should be interpreted accordingly.

Although the terms first, second, third, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or logical changes may be made without departing from the spirit and scope defined by the claims. The description of the embodiments is not limiting. In particular, elements of the embodiments described hereinafter may be combined with elements of different embodiments.

### Example Architecture

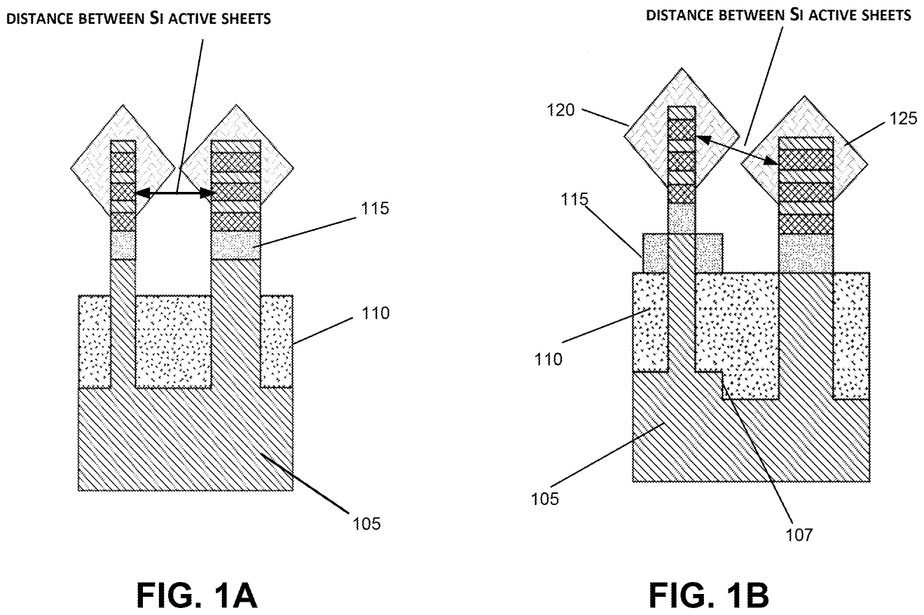

FIG. 1A and FIG. 1B provide a respective front overview of a conventional SRAM cell and an SRAM device with an offset gate stack, consistent with an illustrative embodiment. In both the conventional SRAM of FIG. 1A and the structure in FIG. 1B according to the illustrative embodiment, the materials are the same, substrate 105 disclosed herein can be made of any suitable substrate material, such as, for example, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs) and quaternary (four elements, e.g., aluminum gallium indium phosphide (AlInGaP)) alloys. To facilitate the present discussion, the substrate 105 will be referred to as Si.

There is a step 107 of Si to increase a distance between the active sheets and space the epi S/D further apart to prevent shorting. A shallow trench isolation (STI) 110 of SiO₂ is arranged on top of the substrate 105 and surrounding the gate stacks. A gate spacer material 115 is arranged around the gate stacks. The spacer material can be made of any suitable dielectric material, such as, for example, a low-k dielectric, nitrides, silicon nitride, silicon oxide, SiON, SiC, SiOCN, and SiBCN. In some embodiments of the discloser, the spacer material 115 is a conformal layer deposited over the semiconductor structure followed by an anisotropic etch. An epi S/D 120 for the pull-up PU FET and an epi S/D 125 for the pull-down PD FET are shown as having a difference in heights at least because of the step 107 of Si. The difference in heights reduces the possibility of the epi S/Ds contacting each other and causing device failure without increasing the cell size to space the epi S/Ds apart from each other. In addition, a metal gate height distance (FIG. 1B) of the active sheets SI sheets may also contribute to the different distance in height of the epi S/D 120 and the epi S/D 125 in the case where the gate height is the distance from the top of the nanosheet.

### Process Flow

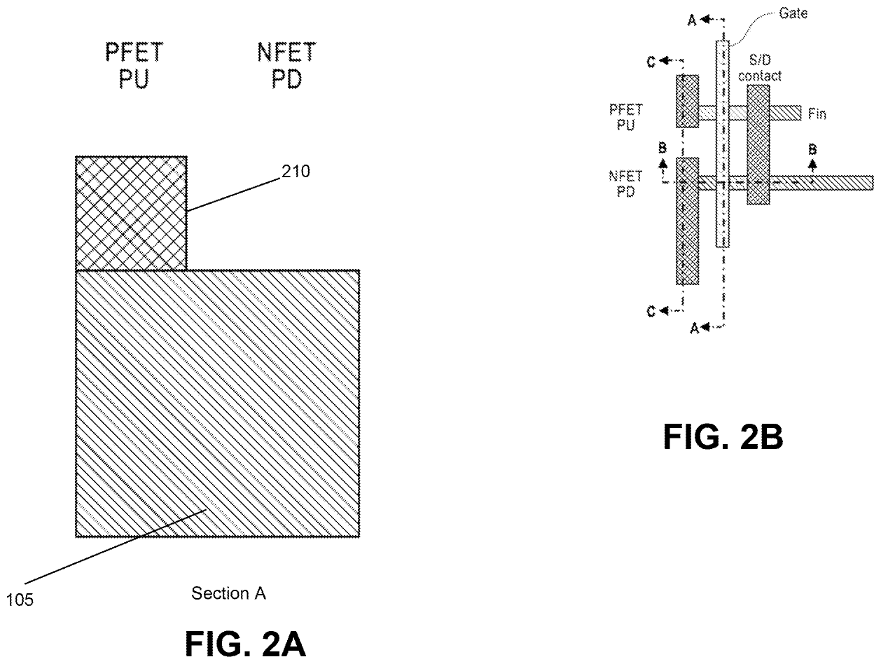

FIGS. 2-14 are process flows illustrating a fabrication method consistent with an illustrative embodiment. A discussion of the entire process flow is provided herein below. For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Fabrication of device depicted in FIGS. 2 to 14 can comprise multi-step sequences of, for example, photolithographic and/or chemical processing steps that facilitate gradual creation of electronic-based systems, devices, components, and/or circuits in a semiconducting and/or a superconducting device (e.g., an integrated circuit). For instance, the device can be fabricated on one or more substrates (e.g., a silicon (Si) substrates, and/or another substrate) by employing techniques including, but not limited to: photolithography, microlithography, nanolithography, nanoimprint lithography, photomasking techniques, patterning techniques, photoresist techniques (e.g., positive-tone photoresist, negative-tone photoresist, hybrid-tone photoresist, and/or another photoresist technique), etching techniques (e.g., reactive ion etching (RIE), dry etching, wet etching, ion beam etching, plasma etching, laser ablation, and/or another etching technique), evaporation techniques, sputtering techniques, plasma ashing techniques, thermal treatments (e.g., rapid thermal anneal, furnace anneals, thermal oxidation, and/or another thermal treatment), chemical vapor deposition (CVD), atomic layer deposition (ALD), physical vapor deposition (PVD), molecular beam epitaxy (MBE), electrochemical deposition (ECD), chemical-mechanical planarization (CMP), backgrinding techniques, and/or another technique for fabricating an integrated circuit.

FIG. 2A shows the forming of an optical planarizing layer (OPL) coating on a substrate for block patterning, consistent with an illustrative embodiment. FIG. 2B shows a top view identifying the cross-section shown in FIG. 2A, consistent with an illustrative embodiment.

A step (e.g., recess) is formed on the substrate 105. One non-limiting example is to form an Optical Planarizing Layer (OPL) coating 210. An etching is then performed to create the step.

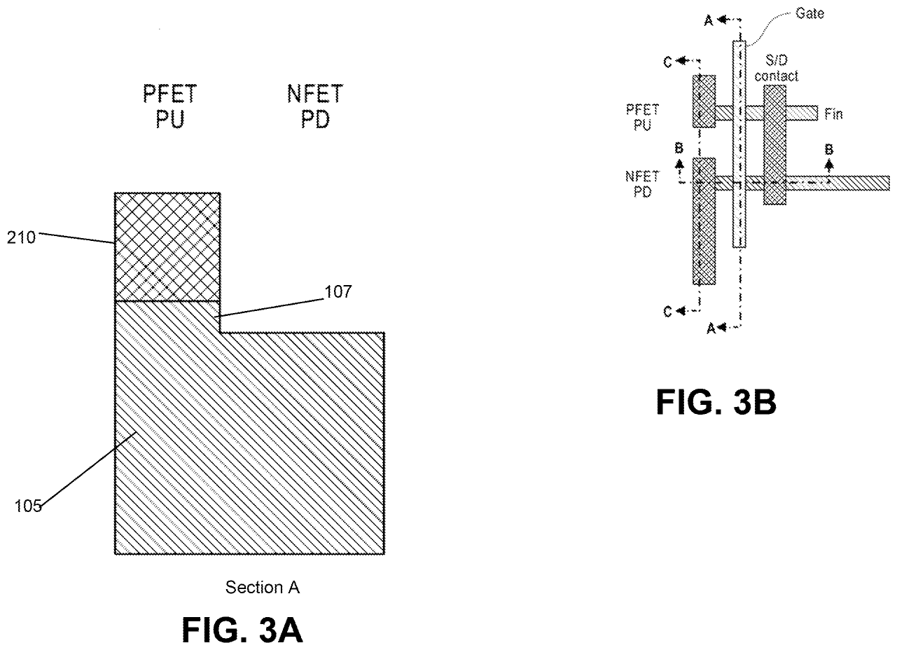

FIG. 3A shows the forming of a recess on the substrate, consistent with an illustrative embodiment. FIG. 3B shows a top view identifying the cross-section shown in FIG. 3A, consistent with an illustrative embodiment. The step 107 is formed on the substrate 105 by an etching process (e.g., lithographic etching).

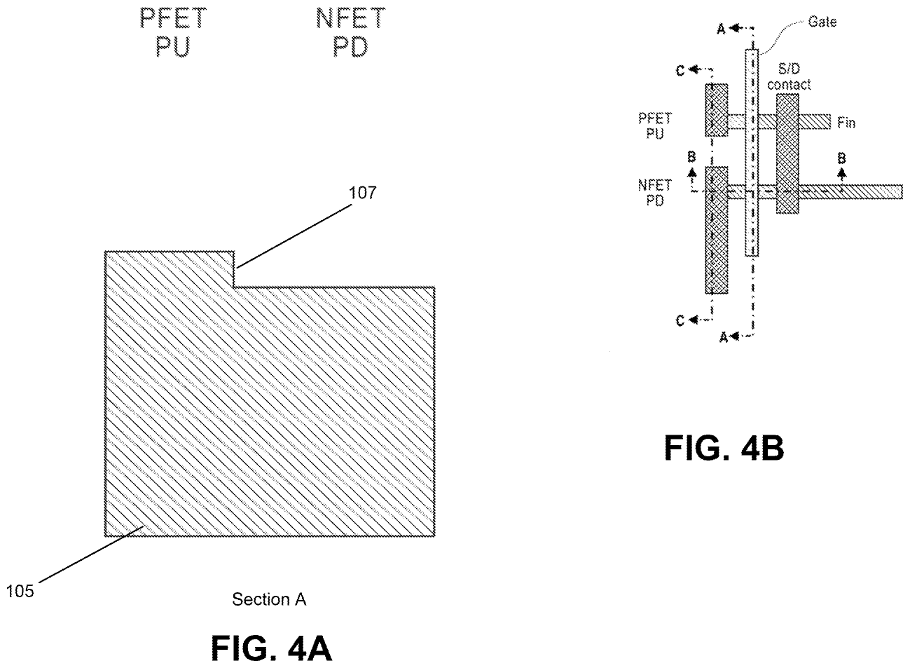

FIG. 4A illustrates the OPL removal from the substrate, consistent with an illustrative embodiment. FIG. 4B shows a top view identifying the cross-section shown in FIG. 4A, consistent with an illustrative embodiment. After removal of the OPL coating 210 shown in FIGS. 2A and 3A, the substrate 105 with the step 107 remains.

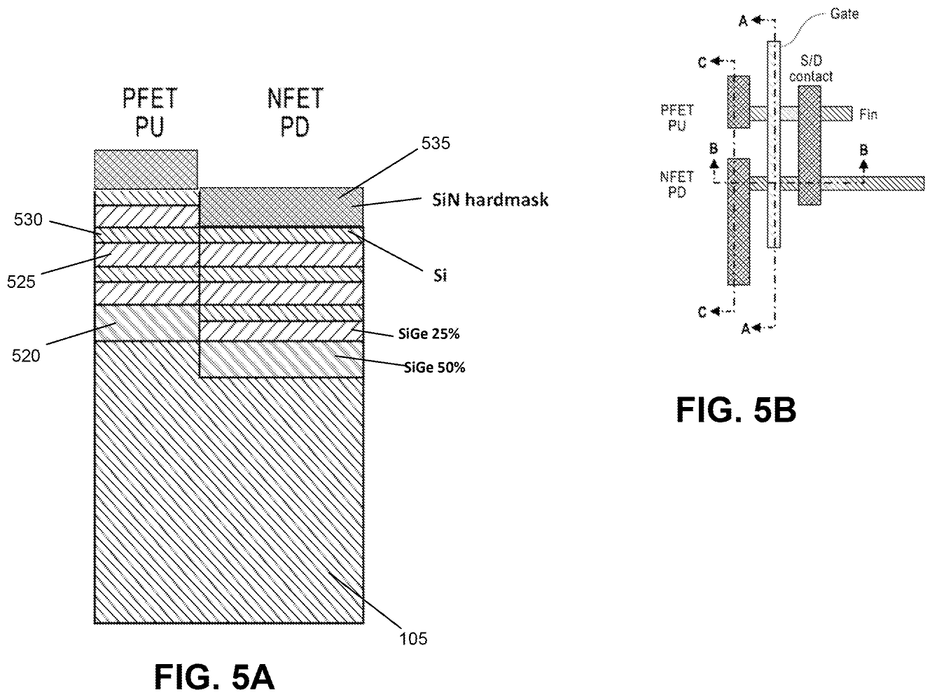

FIG. 5A illustrates the alternating layers of Si/SiGe stack growth, consistent with an illustrative embodiment. FIG. 5B is a top view identifying the cross-sectional views of FIG. 5A consistent with an illustrative embodiment. First, a f SiGe50 layer 520 is arranged on the substrate 105. Then alternating layers of SiGe25 525 and Si 530 are grown on the substrate 105. A hardened SiN mask 535 is also arranged on the alternating layers of Si/SiGe growth. It will be understood that the concentrations of SiGe (e.g., 25, 50, etc.) are provided by way of example only and not by way of limitation. Other concentrations of SiGe are within the scope of the present teachings.

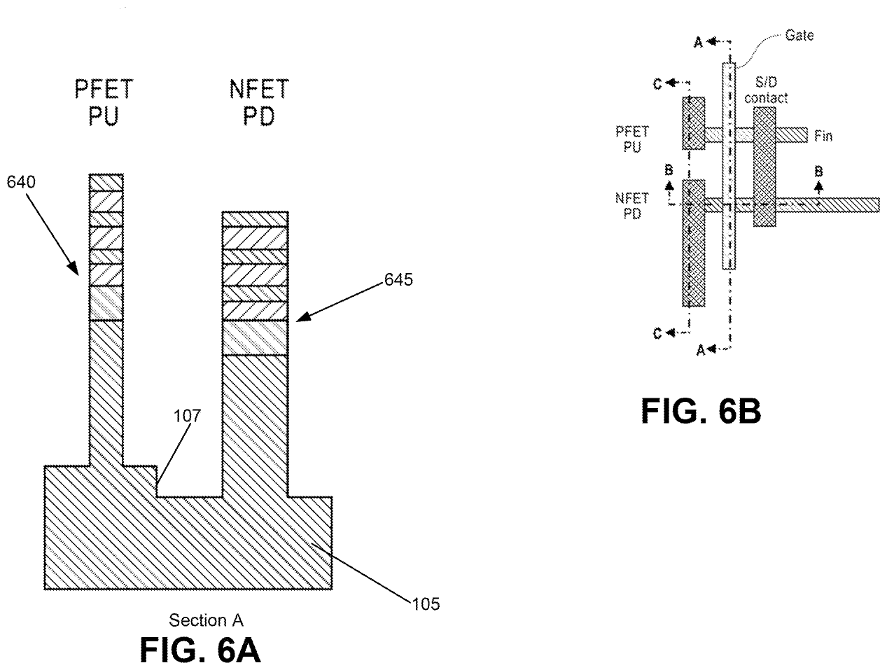

FIG. 6A shows nanosheet patterning of the nanosheet fins from the SI/SiGe stack, consistent with an illustrative embodiment. FIG. 6B is a top view identifying cross-sectional views including cut A of FIG. 6A, consistent with an illustrative embodiment. The nanosheet fin 640 is for the PU PFET device, and the nanosheet fin 645 is for the PD NFET device.

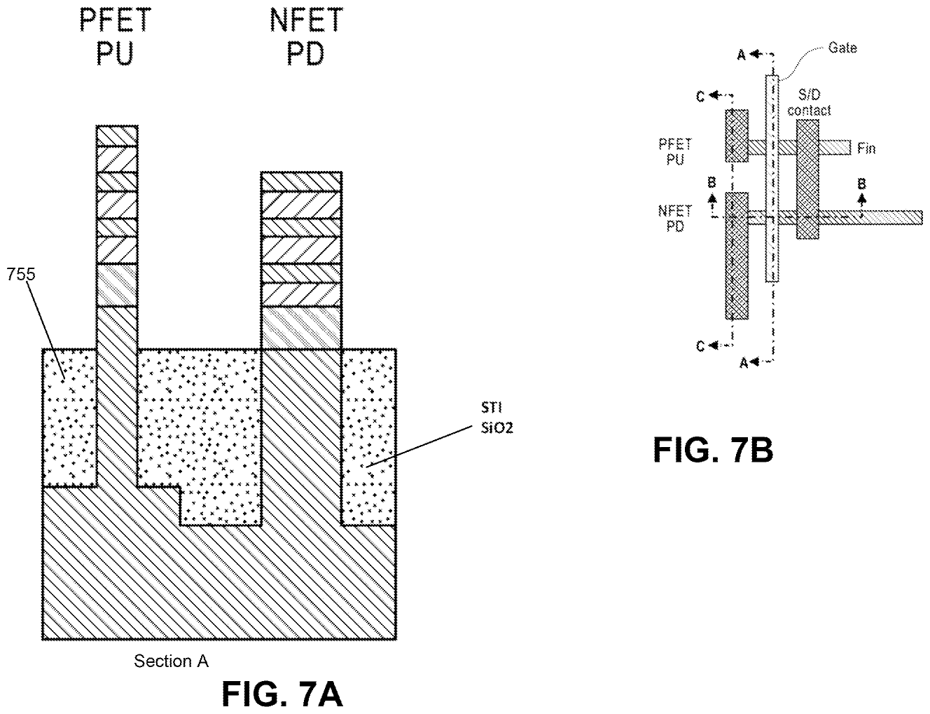

FIG. 7A illustrates a shallow trench isolation (STI) and SiO₂ gap fill of the substrate surface and recess, consistent with an illustrative embodiment. FIG. 7B is a top view identifying the cross-sectional views including cut A of FIG. 7A, consistent with an illustrative embodiment. The SiOₛ material 755 is used to fill the area around the nanosheet fins 640, 645.

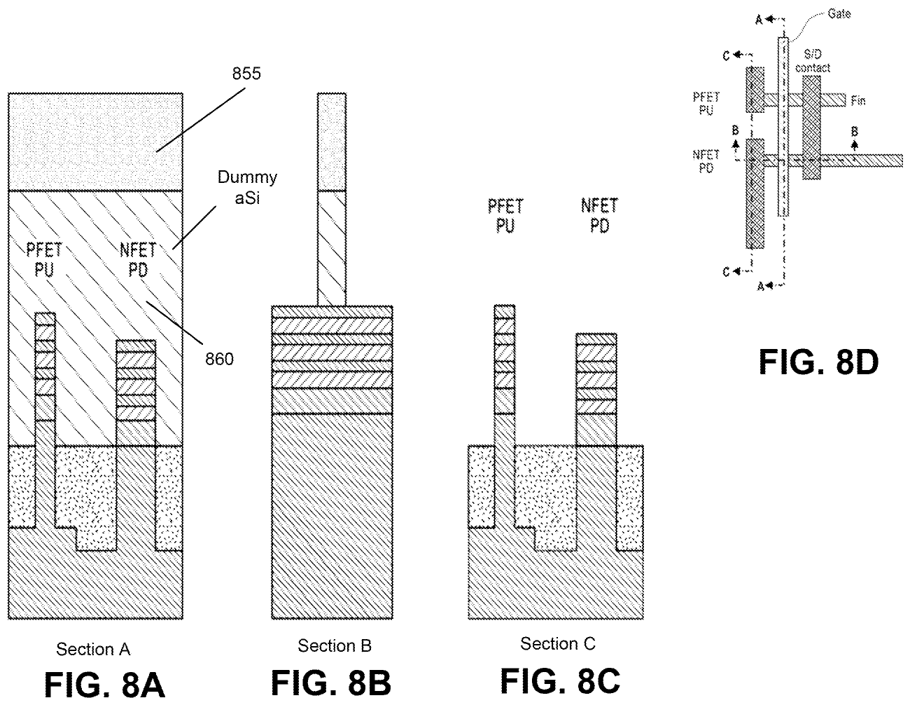

FIGS. 8A, 8B, and 8C are cross-sectional views of a gate patterning operation, consistent with an illustrative embodiment. FIG. 8D is a top view identifying the cross-sectional views (Cut A, Cut B, and Cut C) of FIGS. 8A, 8B, and 8C, consistent with an illustrative embodiment. A Si dummy material 860 and an SiN hardened mask (gate spacer 855) are used to perform the gate patterning.

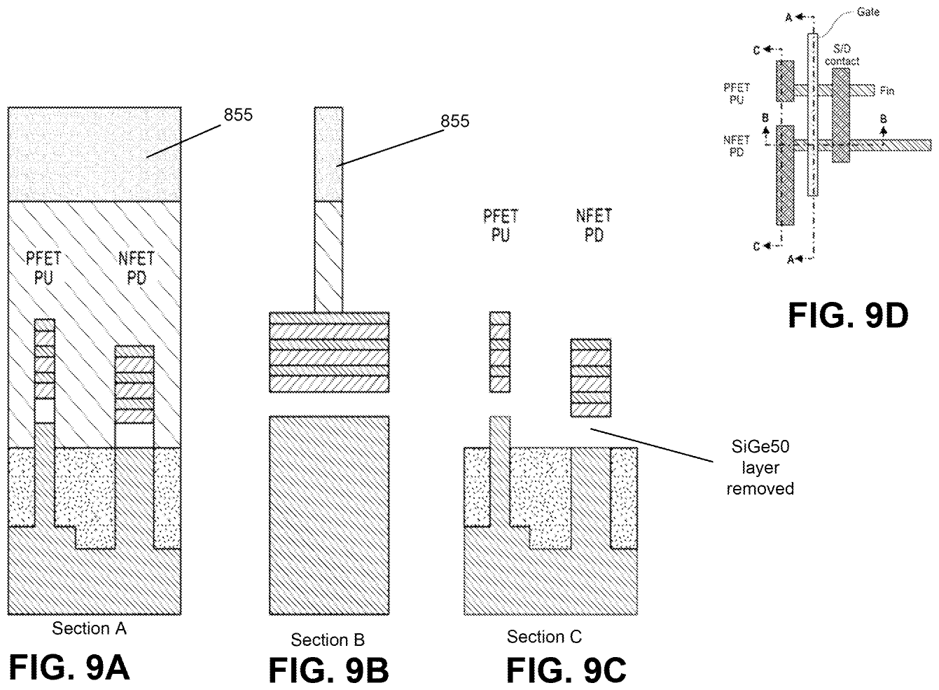

FIGS. 9A, 9B, and 9C are cross-sectional views showing removal of the SiGe 50% layer, consistent with an illustrative embodiment. FIG. 9D is a top view identifying the cross-sectional views (Cut A, Cut B, and Cut C) of FIGS. 9A, 9B, and 9C, consistent with an illustrative embodiment. The SiGe50 layer 520 (first shown in FIG. 5) is removed. In a subsequent operation, a spacer material may be used to fill the spaces with the removed SiGe50 material.

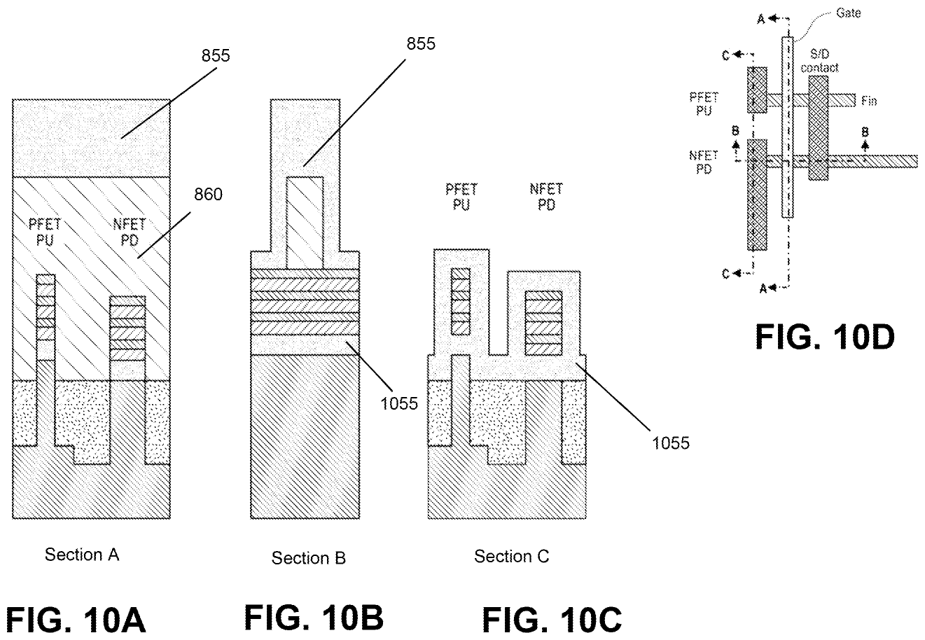

FIGS. 10A, 10B, and 10C are cross-sectional views showing the gate spacer deposition, consistent with an illustrative embodiment. FIG. 10D is a top view identifying the cross-sectional views (Cut A, Cut B, and Cut C) of FIGS. 10A, 10B, and 10C, consistent with an illustrative embodiment. The gate spacer 855 deposition may be an SiN or SiO₂ material and will also fill in the removed SiGe50 material. The material may be referred to as a Bottom Dielectric Isolation (BDI) alternating stack layer 1055 as it insulates the alternating stack from substrate.

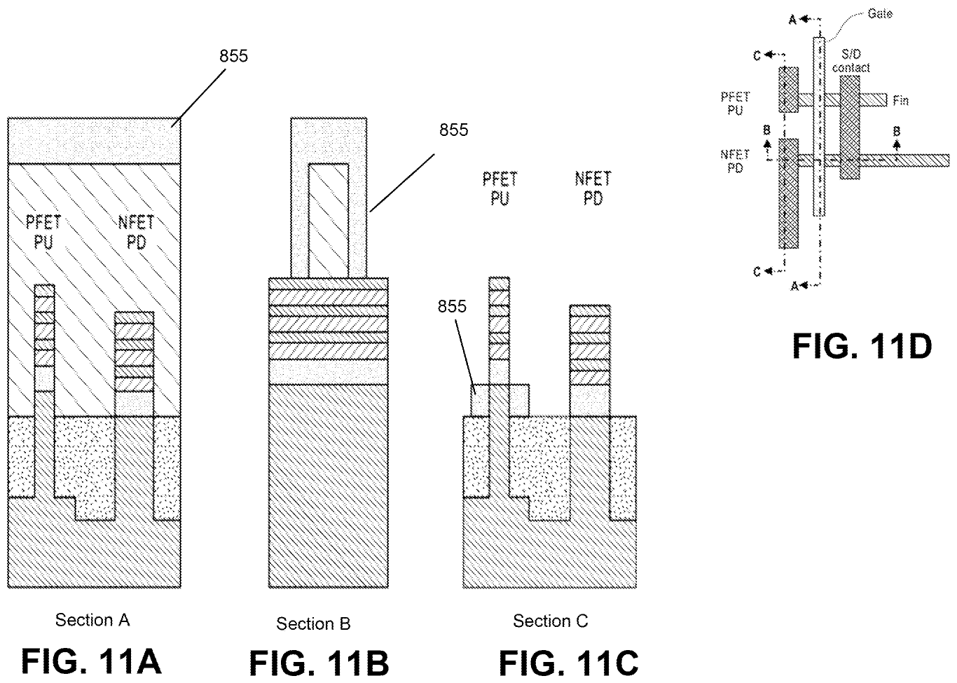

FIGS. 11A, 11B, and 11C are cross-sectional views showing the gate spacer being etched back, consistent with an illustrative embodiment. FIG. 11D is a top view identifying the cross-sectional views (Cut A, Cut B and Cut C) of FIGS. 11A, 11B, and 11C, consistent with an illustrative embodiment. The gate spacer 855 (e.g., SiN or SiO₂ material) is etched back and it shown there is less material 855 than compared with FIG. 10A-10C. However, the spacer material remains around the pull-up PU, but it is scaled back around the PD.

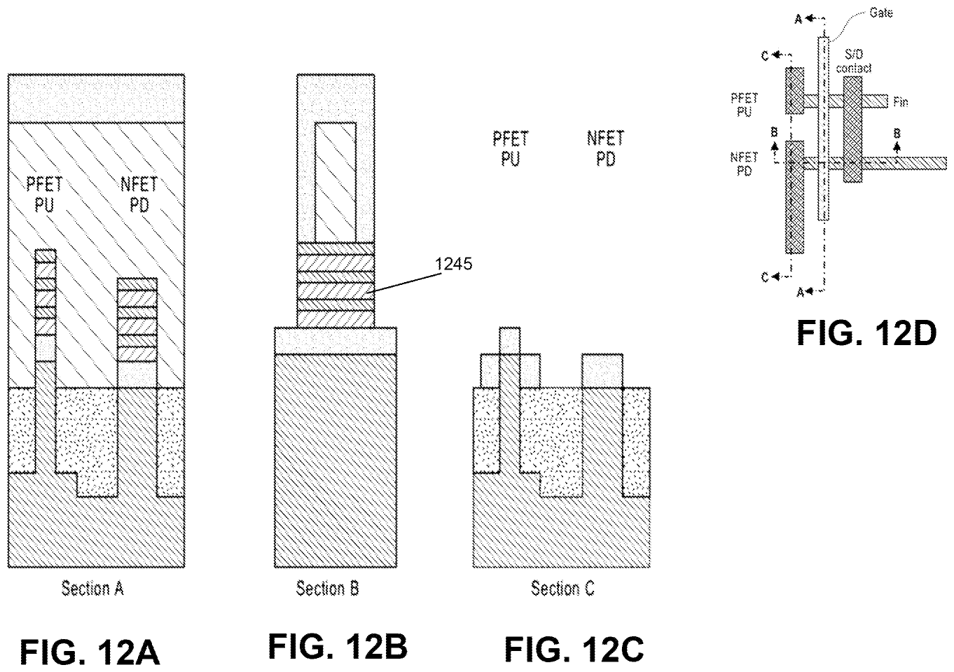

FIGS. 12A, 12B, and 12C are cross-sectional views a nanosheet pull-down of the spacer pull-down at a sidewall of the nanosheets, consistent with an illustrative embodiment. FIG. 12D is a top view identifying the cross-sectional views (Cut A, Cut B, and Cut C) of FIGS. 12A, 12B, and 12C, consistent with an illustrative embodiment. Compared with FIG. 11B, the nanosheet gate stack 1245 in FIG. 12B is narrower.

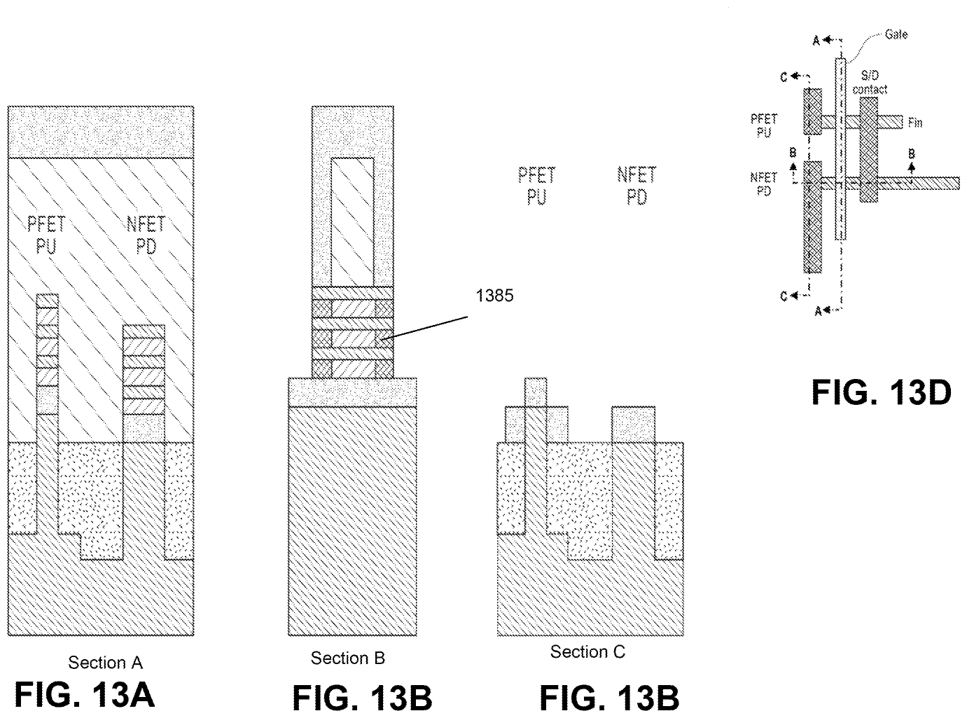

FIGS. 13A, 13B, and 13C are cross-sectional views of an inner space formation of a nanosheet recess, consistent with an illustrative embodiment. FIG. 13D is a top view identifying the cross-sectional views (Cut A, Cut B, and Cut C) of FIGS. 13A, 13B, and 13C, the inner space formation 1385 is arranged on the gate stack. The inner spacers may be formed, for example, consistent with an illustrative embodiment. It is shown in FIG. 13B that the inner spacer formation can be made using a CVD, PECVD, ALD, PVD, chemical solution deposition, or other like processes in combination with a wet or dry etch process. The inner spacers can be made of any suitable material, such as, for example, a low-k dielectric, a nitride, silicon nitride, silicon dioxide, SiON, SiC, SiOCN, or SiBCN.

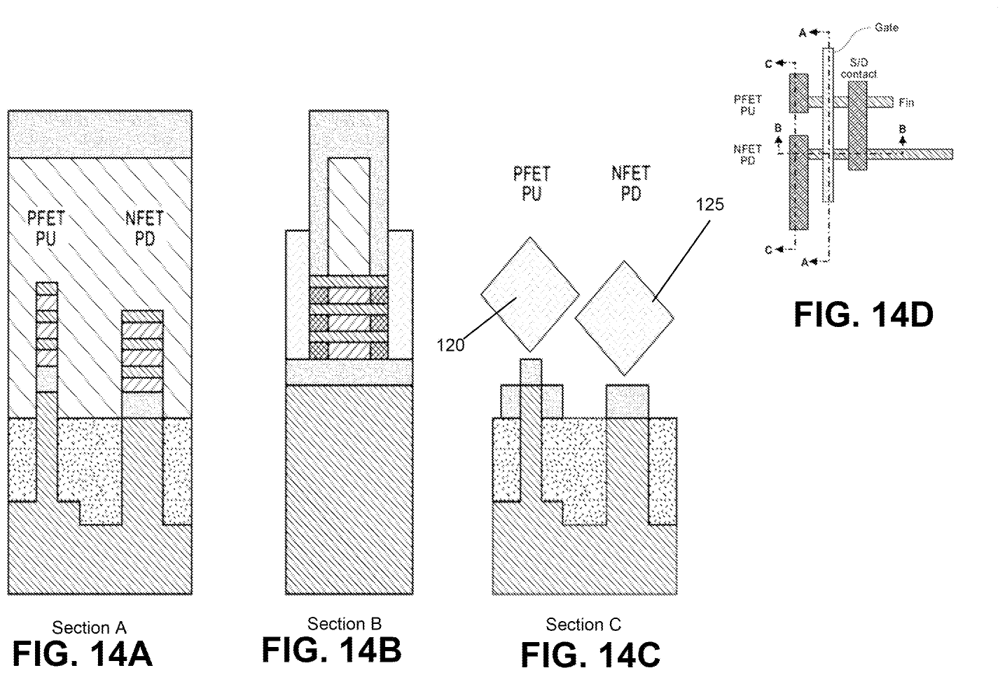

FIGS. 14A, 14B, and 14C are cross-sectional views of an S/D epi growth at the sidewalls of the nanosheets, consistent with an illustrative embodiment. FIG. 14D is a top view identifying the cross-sectional views (Cut A, Cut B, and Cut C) of FIGS. 14A, 14B, and 14C, consistent with an illustrative embodiment. The epi S/D 120, 125 (originally shown in FIG. 1B) is spaced apart from each by the offset to reduce the possibility of the adjacent S/D shorting.

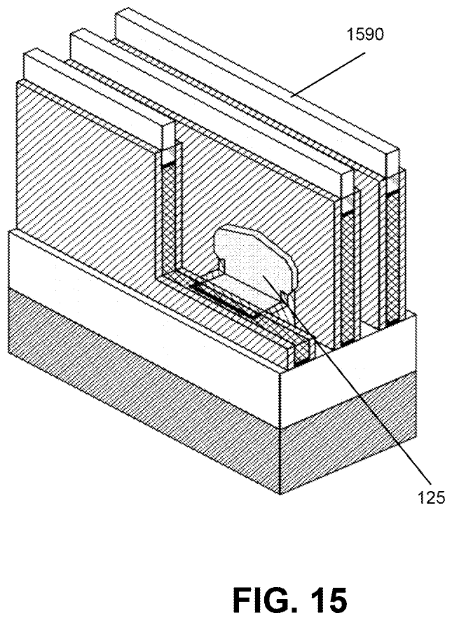

FIG. 15 is a perspective view of a general semiconductor device. FIG. 15 shows a perspective view showing the epi S/D 125 grows from the exposed nanosheet at side of the gate, which can help to understand the S/D epi formation in FIG. 14C.

### Example Process

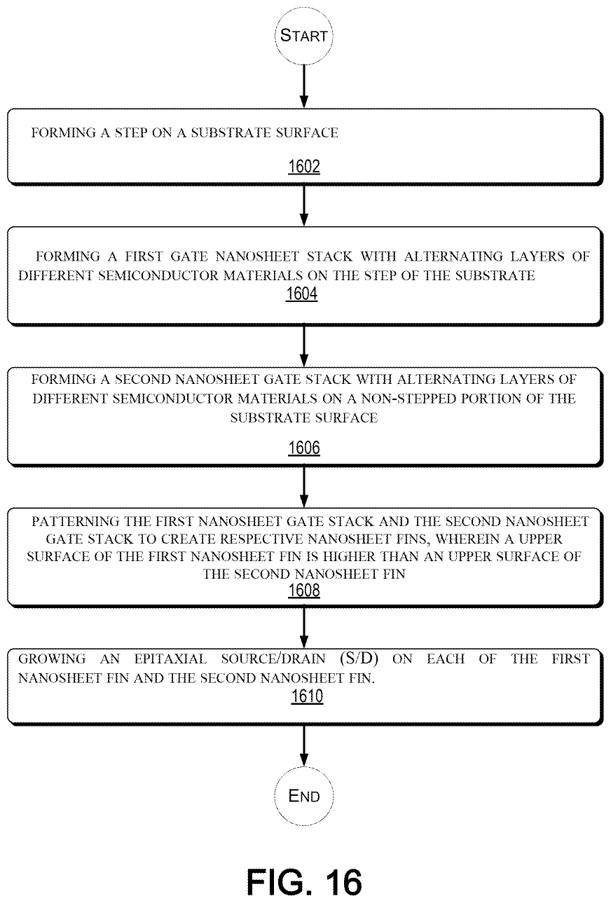

With the foregoing overview of the example architecture, it may be helpful now to consider a high-level discussion of an example process. To that end, FIG. 16 is a flowchart illustrating a method of forming a semiconductor device, consistent with an illustrative embodiment.

FIG. 16 is shown as a collection of blocks, in a logical order, which represents a sequence of operations that can be implemented in hardware, software, or a combination thereof. In each process, the order in which the operations are described is not intended to be construed as a limitation, and any number of the described blocks can be combined in any order and/or performed in parallel to implement the process. Some of the drawings in conjunction with the process flow of FIGS. 2-15 will be referenced to illustrate some of the operations in FIG. 16.

At operation 1602, a step (e.g., recess) is formed on the substrate. One non-limiting example is to form an Optical Planarizing Layer (OPL) coating such as shown in FIG. 2A, followed by the forming of a recess in the substrate shown in FIG. 3A. The recess may be formed by an etching process.

At operation 1604, a first gate nanosheet stack is formed on the step of the substrate that includes alternating layers of different semiconductor materials on the semiconductor surface. For example, FIG. 5A shows alternating layers of Si and SiGe. The SiGe alloy used for the alternating layers may be SiGe25.

At operation 1606, a second gate nanosheet stack is formed on the non-stepped surface of the substrate that includes alternating layers of different semiconductor materials on the semiconductor surface. The alternating layers are the same as described above with regard to operation 1604.

At operation 1608, the first and second nanosheet gate stacks are patterned into fins. FIG. 6A shows the fin for the PU FET, and the fin for the PD FET. The PU fin is higher than the PD fin at least due to the step on the substrate.

At operation 1610, an epitaxial source/drain (epi S/D) is grown on each of the first nanosheet fin and the second nanosheet fin. FIG. 14 shows the epi S/D being diamond shaped. The basic operation of the method ends at 1610. However, there are several operations in the process flow of FIGS. 2-14 that may be performed to enhance the structure shown.

With regard to the method described above in the flowchart of FIG. 16, it will be understood that this embodiment is not exhaustive of the scope of the disclosure. For example, the process flow of FIGS. 2 to 14 discloses additional operations that may be performed in the fabrication of the semiconductor device according to the various illustrative embodiments.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings. For example, while the substrate is disclosed as being Si, it may be made of other materials.

The components, operations, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

The flowcharts, and diagrams in the figures herein illustrate the architecture, functionality, and operation of possible implementations according to various embodiments of the present disclosure.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any such actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device comprising:
a first nanosheet field effect transistor (FET) having a first gate stack, arranged on a substrate; and
a second nanosheet FET having a second gate stack, arranged on the substrate adjacent to the first nanosheet FET,
wherein a top of the first gate stack and a top of the second gate stack are at different heights.

2. The semiconductor device of claim 1, further comprising:
a first channel of the first gate stack extending from a bottom of the first gate stack and having a first height; and
a second channel of the second gate stack extending from a bottom of the second gate stack and having a second height,
wherein the first height of the first channel is different than the second height of the second channel based on a difference in channel heights of the substrate.

3. The semiconductor device of claim 2, wherein the first height of the first channel is different than the second height of the second channel additionally based on a metal gate height having a distance between two adjacent channels on the top of the first gate stack and the top of the second gate stack.

4. The semiconductor device of claim 1, wherein the first FET comprises a pull-up (PU) PFET, and the second FET comprises a pull-down (PD) NFET.

5. The semiconductor device of claim 4, wherein a source/drain (S/D) epitaxial growth on the PU PFET and on the PD NFET are offset by a difference in channel height of the first height of the first channel and the second height of the second channel.

6. The semiconductor device of claim 4, wherein:
the substrate comprises a stepped upper surface;
the PU PFET is arranged on the stepped upper surface of the substrate; and
the PD NFET is arranged a non-stepped upper surface of the substrate.

7. The semiconductor device of claim 4, further comprising a shallow trench isolation (STI) SiO₂ recess connected to the PU PFET and the PD NFET of different depths on an upper surface of the substrate.

8. The semiconductor device of claim 1, wherein:
the substrate comprises a silicon (Si) pattern with different recess depths; and
the substrate is arranged below a Bottom Dielectric Isolation (BDI) layer.

9. The semiconductor device of claim 8, wherein there are a same number of nanosheets for each nanosheet FET on the Si pattern.

10. The semiconductor device of claim 8, wherein:
there are a same number of nanosheets having a same total nanosheet height; and
the total nanosheet height comprises a channel height, a dummy SiGe layer, and the BDI layer.

11. A method of preventing a source/drain (S/D) epi merge, comprising:
providing a first nanosheet fin including a first field effect transistor (FET) having a first gate stack, on a substrate; and
providing a second nanosheet fin including a second FET having a second gate stack on the substrate adjacent to the first nanosheet fin,
wherein a first top of the first gate stack is a different height than a second top of the second gate stack.

12. The method according to claim 11, further comprising forming a step on a surface of the substrate such that the first gate stack is offset in height from the second gate stack.

13. The method according to claim 12, wherein the first nanosheet fin and the second nanosheet fin formed on the substrate have equal lengths.

14. The method according to claim 12, wherein:
the first nanosheet fin is provided on a higher portion of the stepped substrate surface; and
the second nanosheet fin is provided on a lower portion of the stepped substrate surface.

15. The method according to claim 14, wherein the first FET provided on the first nanosheet fin comprises a pull-up (PU) PFET, and the second FET provided on the second nanosheet fin comprises a pull-down (PD) NFET.

16. The method according to claim 11, further comprising:
providing a first channel that extends from a bottom of the first gate stack and has a first height; and
providing a second channel that extends from a bottom of the second gate stack and has a second height,
wherein the first height of the first channel is different than the second height of the second channel by at least a difference in channel heights of the substrate.

17. The method according to claim 16, further comprising providing a first metal gate on the first nanosheet FET and a second metal gate on the second nanosheet FET, wherein the first height of the first channel is different than the second height of the second channel by the difference in channel heights and by a metal gate height distance between the first channel and the second channel on the first top of the first gate stack and the second top of the second gate stack.

18. A method of forming a semiconductor device, the method comprising:
forming a stepped portion on a substrate surface;
forming a first gate nanosheet stack with alternating layers of different semiconductor materials on the stepped portion of the substrate surface;
forming a second nanosheet gate stack with alternating layers of different semiconductor materials on a non-stepped portion of the substrate surface;
patterning the first nanosheet gate stack and the second nanosheet gate stack to create respective nanosheet fins, wherein an upper surface of a first nanosheet fin is higher than an upper surface of a second nanosheet fin; and
growing an epitaxial source/drain (S/D) on each of the first nanosheet fin and the second nanosheet fin.

19. The method according to claim 18, wherein the epitaxial S/D is grown on a side of each nanosheet fin and has different respective height on the stepped portion of the substrate surface and the non-stepped portion of the substrate surface.

20. The method according to claim 18, wherein:
the alternating layers of different semiconductor materials include Si and SiGe; and
the method further comprises providing an STI of SiO₂ on surface of the substrate.
